(19) United States
(12) Patent Application Publication
(10) Pub. No.: US 2026/0310096 A1
(43) Pub. Date: Oct. 8, 2026

(54) METHOD FOR STITCHING LINES

(71) Applicant: Tokyo Electron Limited, Tokyo (JP)

(72) Inventors: Sheldon Meyers, Albany, NY (US); Steven Gueci, Albany, NY (US)

(21) Appl. No.: 19/170,755

(22) Filed: Apr. 4, 2025

(51) Int. Cl. G03F 7/00; G03F 1/22

(52) U.S. Cl. CPC G03F 7/70475; G03F 1/22; G03F 7/70033; G03F 7/70433

(57) ABSTRACT

A method of processing a substrate includes exposing a first region of a photosensitive layer of the substrate to structured radiation through a first photomask and exposing a second region of the photosensitive layer to structured radiation through a second photomask. The first photomask includes a first transparent area and a first transparent line-end extending from the first transparent area. The first transparent line-end is positioned over a stitching region adjacent the first region. The second region is adjacent the stitching region opposite the first region. The second photomask includes a second transparent area and a second transparent line-end extending from the second transparent area. The second transparent line-end is positioned over the stitching region.

### TECHNICAL FIELD

The present invention relates generally to semiconductor fabrication, and, in particular embodiments, to systems and methods for reducing stitching defects between stitched features.

### BACKGROUND

The formation of microscale and nanoscale structures within a workpiece, such as within an integrated circuit (e.g., semiconductor fabrication), involves a series of processing techniques that include forming, patterning, and removing various layers of material on a substrate. Lithography processes enable the transfer of patterns onto a substrate, and include photolithography processes that use structured radiation (e.g., light of a specific wavelength or narrow range of wavelengths, such as actinic radiation) to pattern a layer of photosensitive material (photoresist) on the substrate. During the exposure process, the actinic radiation causes a change in the chemical structure of the photoresist that makes it more susceptible (positive tone) or less susceptible (negative tone) to being removed during a subsequent development process. When the exposed photoresist layer is developed, desired regions of the photoresist are removed leaving the pattern behind on the substrate.

The various types of photolithography can be categorized by the wavelength of the radiation as well as other attributes of the exposure process, such as the medium through which the radiation propagates (gas, liquid, vacuum, etc.), the numerical aperture of the lens, and others. Among other things, these attributes affect the resolution capabilities of the photolithography process. For example, ultraviolet (UV) lithography processes, such as i-line lithography, use wavelengths in the ultraviolet range (e.g., 365 nm), deep ultraviolet (DUV) lithography processes use wavelengths in the range of about 190 nm to about 250 nm, while extreme ultraviolet (EUV) lithography processes use even shorter wavelengths, such as 13.5 nm wavelength. As the wavelength decreases, the achievable feature size also decreases (i.e., improved resolution).

Changing the propagation medium (such as from air to liquid as in immersion lithography) can further decrease the attainable feature size. The numerical aperture of the projection lens can also be increased to improve the resolution of the lithography process for any wavelength. For example, since the diffraction limit of a lithography process is inversely proportional to the numerical aperture, increasing the numerical aperture is desirable to lower the diffraction limit allowing better resolution, such as in EUV lithography processes. However, higher numerical apertures also affect other aspects of the photolithography process, such as the maximum achievable exposure field size (i.e., the size of the exposed pattern on a substrate relative to the mask size). Specifically, various factors of higher numerical aperture systems, such as increased lens complexity/size and uniformity challenges can decrease the maximum exposure field.

To counteract the smaller exposure field, the mask size may be increased. However, this can be prohibitively expensive, requiring extensive changes to equipment and processes. Alternatively, multiple regions may be exposed on the same substrate (e.g., more than one exposure in a single die, for example). The regions where the exposure fields connect are often referred to as stitching regions.

Current augmented reality (AR) and virtual reality (VR) glasses require field sizes larger than the standard 26 mm x 33 mm used on most lithographic scanners that require below 100 nm resolution. As a result, two fields are seamlessly stitched together to form one product chip. The stitching performance depends on the line-end imaging in which a burl, or in other words a bulge, forms on the line at the stitching point. The current practice utilizes a standard square edge which can result in noticeable burl stitching defects.

Stitching has become increasingly relevant with the advent of high numerical aperture (NA) EUV technology which employs an anamorphic lens design that reduces field size in the Y direction to 26 mm by 16.5 mm. This field size reduction necessitates stitching at all advanced nodes for ASIC or DRAM production. The process window is particularly sensitive to overlay errors at the stitching points. However, precise alignment of exposure fields can be difficult, leading to stitching defects, such as undesirable extra material or misplaced material in the stitching region. Further, even with precise alignment, stitching defects cannot be entirely avoided in many cases due to the need for some overlap between the exposure fields (e.g., to ensure that the patterns connect to one another, such as for waveguides that meet at stitch points).

### SUMMARY

In accordance with an embodiment, a method of processing a substrate includes: exposing a first region of a photosensitive layer of the substrate to structured radiation through a first photomask, the first photomask including a first transparent area and a first transparent line-end extending from the first transparent area, the first transparent line-end being positioned over a stitching region adjacent the first region, the first transparent area having a first width, the first transparent line-end having a second width smaller than the first width; and after exposing the first region, exposing a second region of the photosensitive layer to structured radiation through a second photomask, the second region being adjacent the stitching region opposite the first region, the second photomask including a second transparent area and a second transparent line-end extending from the second transparent area, the second transparent line-end being positioned over the stitching region.

In accordance with another embodiment, a method of processing a substrate includes: forming a photoresist over the substrate, the photoresist including a first region, a second region, and a stitching region between the first region and the second region; exposing the first region to extreme ultraviolet (EUV) radiation through a first transparent area and a first transparent line-end extending from the first transparent area over the stitching region, the first transparent line-end being narrower than the first transparent area; exposing the second region to EUV radiation through a second transparent area and a second transparent line-end extending from the second transparent area over the stitching region, the second transparent line-end being narrower than the second transparent area; and forming a pattern of lines on the substrate by developing the first region, the second region, and the stitching region, the pattern of lines including a first subset of lines in the first region and a second subset of lines in the second region, the first subset of lines being stitched to the second subset of lines in the stitching region.

In accordance with yet another embodiment, a method of processing a substrate includes: generating a plurality of line patterns by performing a stitching process, the stitching process using a plurality of overlap distances between a top portion and a bottom portion of a line-end shape; measuring a respective overlay figure for each overlap distance of the plurality of overlap distances; selecting an overlap distance for achieving a desired overlay figure using the respective overlay figures; and forming a pattern of lines on the substrate using the selected overlap distance for the stitching process.

It is to be understood that both the foregoing general description and the following detailed description are exemplary and explanatory only and are not restrictive of the disclosure, as claimed.

### BRIEF DESCRIPTION OF THE DRAWINGS

For a more complete understanding of the present invention, and the advantages thereof, reference is now made to the following descriptions taken in conjunction with the accompanying drawings, in which:

FIG. 1 illustrates an example photolithography system that includes a photomask through which two fields on a substrate are separately exposed, in accordance with some embodiments;

FIG. 2 illustrates an example photolithography system that includes a photomask that is used to form a pattern of lines on a substrate using two separate exposure fields, in accordance with some embodiments;

FIGS. 3, 4, 5, 6, and 7 illustrate photomasks with specialized line-end shapes, in accordance with some embodiments;

FIG. 8 illustrates a process flow chart diagram for a method of processing a substrate, in accordance with some embodiments;

FIG. 9 illustrates a process flow chart diagram for a method of processing a substrate, in accordance with some embodiments;

FIG. 10 illustrates a process flow chart diagram for a method of processing a substrate, in accordance with some embodiments.

Corresponding numerals and symbols in the different Figures generally refer to corresponding parts unless otherwise indicated. The Figures are drawn to clearly illustrate the relevant aspects of the embodiments and are not necessarily drawn to scale. The edges of features drawn in the Figures do not necessarily indicate the termination of the extent of the feature.

### DETAILED DESCRIPTION OF ILLUSTRATIVE EMBODIMENTS

The making and using of various embodiments are discussed in detail below. It should be appreciated, however, that the various embodiments described herein are applicable in a wide variety of specific contexts. The specific embodiments discussed are merely illustrative of specific ways to make and use various embodiments, and should not be construed in a limited scope.

The maximum achievable exposure field size for a given mask size is already small (e.g., smaller than an individual die at times). Yet current EUV projection lenses also have relatively low numerical apertures, such as in the range of 0.33. Higher numerical aperture (NA) EUV projection lenses are being developed, targeting 0.55 and even higher. These High-NA EUV projection lenses will have an even smaller achievable exposure field size. Therefore, while stitching defects between features formed with separate exposure fields may be a problem for any type of photolithography, the problem may be especially important for High-NA EUV photolithography processes. Unfortunately, current techniques to reduce stitching defects may lack the fine control necessary to avoid damaging the non-defect regions of the stitched features.

According to one or more embodiments of the present disclosure, this application relates to methods of reducing stitching defects by implementing line-end structures for seamless stitching between exposure fields. In various embodiments, various line-end designs are utilized to reduce burl size and modulate the shape at stitching points. The line-end structures include dovetail, staggered, and tapered configurations that provide optical proximity correction features at the stitching interface. These specialized line-end structures increase the stitching process window by reducing the effects of overlay errors at the stitching points. In one or more embodiments, the dovetail design demonstrates improved performance by producing a smoother burl compared to standard square edge configurations. The disclosed structures are particularly advantageous for future advanced node stitching applications, including high numerical aperture extreme ultraviolet (EUV) lithography processes for which precise stitching techniques are useful to address field size limitations.

In various embodiments, the method of processing the substrate includes forming the pattern of lines on the substrate using two exposures of a photosensitive layer (i.e., two exposure fields, which may use the same photomask). For example, a first exposure may use structured radiation (e.g., ultraviolet (UV), deep ultraviolet (DUV), or extreme ultraviolet (EUV) radiation) to expose a first region of the photosensitive layer while a separate, second exposure may use structured radiation (i.e., different from the first exposure, such as through a different reticle stage and the same photomask, a different exposure performed after the first exposure, etc.) to expose a second region of the photosensitive layer. The pattern of lines may then be formed by developing the first region and the second region. The pattern of lines formed by developing the exposed regions may be subsequently transferred to an underlying layer by etching the underlying layer using the developed photosensitive layer as an etch mask.

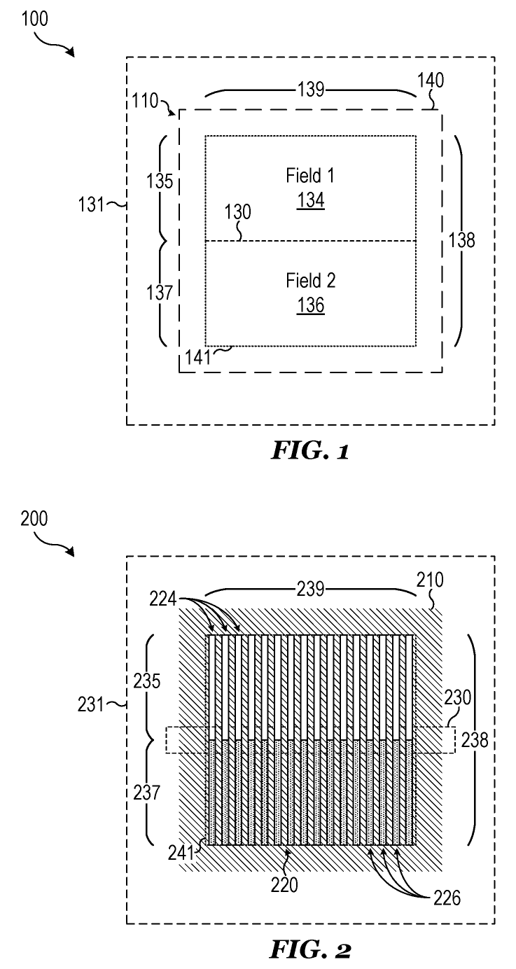

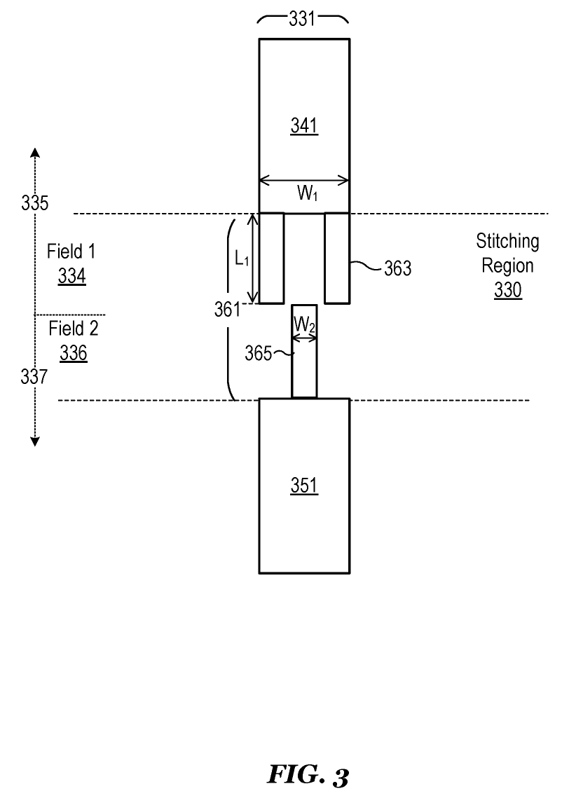

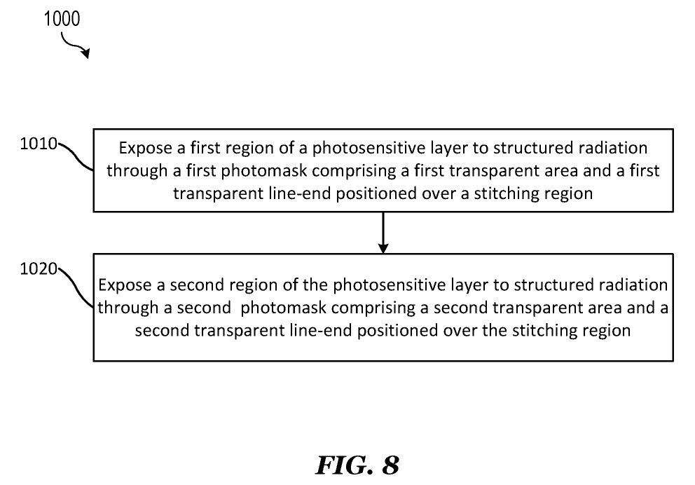

Embodiments of the disclosure are described in the context of the accompanying drawings. FIGS. 1 and 2 are used to describe example photolithography systems that use separate exposure fields stitched together. FIGS. 3, 4, 5, 6, and 7, are used to describe embodiments of photomasks with specialized line-end shapes. FIGS. 8, 9, and 10 are used to describe methods of processing a substrate.

FIG. 1 schematically illustrates an example photolithography system that includes a photomask through which two fields on a substrate are separately exposed, in accordance with some embodiments. Referring to FIG. 1, a photolithography system 100 includes a substrate 110 that has a first exposure field 134 and a second exposure field 136. The first exposure field 134 and the second exposure field 136 are spatially separate and directly adjacent to one another so that the fields connect in a stitching region 130. A photomask 131 may be used to expose one or both of the first exposure field 134 and the second exposure field 136 (e.g., expose a photosensitive layer 140) as part of a lithography process that forms features on the substrate 110. For example, a pattern of lines may be formed on the substrate 110 using the lithography process and the photomask 131 may define a subset of lines that are projected separately to both the first exposure field 134 and the second exposure field 136 and stitched together in the stitching region 130.

As a non-limiting example, the photomask 131 includes multiple layers deposited on a low thermal expansion material (LTEM) substrate. The LTEM substrate comprises a material with near-zero thermal expansion properties, such as glass (e.g., fused silica) or glass-ceramic compounds. In various examples, the LTEM substrate has a thickness between about 6.25 mm and 6.5 mm, such as 6.4 mm. However, the LTEM substrate may have any suitable thickness. In some embodiments, the backside of the LTEM substrate is coated with a conductive material (e.g., chromium nitride (CrN) with a thickness in a range of 70 nm to 100 nm) so that an electrostatic chuck (ESC) can hold the photomask 131 in a vacuum. A multilayer reflector stack is formed on the LTEM substrate. In various embodiments, the multilayer reflector comprises alternating layers of molybdenum and silicon, with the alternating layers having thicknesses in a range of about 3 nm to 4 nm and the multilayer reflector stack having a total thickness in a range of about 250 nm to 350 nm. However, the alternating layers may have any suitable thicknesses and comprise any suitable materials. In some examples, the multilayer reflector includes 40 to 50 pairs of alternating molybdenum and silicon layers. An absorption layer is formed on the multilayer reflector stack. In various examples, the absorption layer comprises tantalum-based compounds such as tantalum boron nitride (TaBN), tantalum boron oxide (TaBO), tantalum nitride (TaN), the like, or a combination thereof, and has a thickness between about 50 nm and 75 nm to provide sufficient absorption of EUV radiation. However, the absorption layer may comprise any suitable materials and have any suitable thickness. The absorption layer is patterned to permit radiation to pass through in a desired exposure pattern. In some examples, a capping layer comprising ruthenium or silicon is formed between the multilayer reflector and the absorption layer to prevent or reduce interdiffusion and oxidation. The capping layer may have, for example, a thickness between about 2 nm and 4 nm, such as about 2.5 nm of ruthenium or 4 nm of silicon. A buffer may be formed between the capping layer and the absorption layer. In various examples, the buffer layer comprises chromium or chromium nitride with a thickness between about 2 nm and 5 nm. The buffer layer enhances etch selectivity during patterning of the absorption layer and protects the underlying capping layer during repair processes.

In various embodiments, the photolithography system 100 includes a reticle stage that holds the photomask 131 and a wafer stage that holds the substrate 110. The reticle stage maintains the photomask 131 in a fixed position while the wafer stage provides precise positioning of the substrate 110. In one or more embodiments, the wafer stage employs laser interferometry for position measurement and feedback control to achieve positioning accuracy within nanometers. For stitching multiple exposure fields, the wafer stage moves the substrate 110 to different positions relative to the stationary photomask 131. In one or more embodiments, the wafer stage performs a step-and-scan motion, where the stage steps to a new position for each exposure field and then scans during the exposure. The scanning motion occurs in synchronization with the reticle stage, which moves only during exposure to scan the pattern across the field. In high numerical aperture (high-NA) EUV systems, the exposure field size is limited to, for example, approximately 26 mm x 16.5 mm due to the anamorphic optical design. To pattern larger die areas, the wafer stage positions the substrate for multiple exposures that are stitched together. The stage control system maintains precise alignment between adjacent exposure fields to minimize stitching errors. In various embodiments, alignment marks on the substrate 110 can provide feedback for positioning subsequent exposure fields relative to previously exposed patterns. The stitching process benefits careful control of both the wafer stage position and the exposure dose in the overlap region between fields. In one or more embodiments, the exposure dose is modulated near the field boundaries to achieve uniform pattern transfer in the stitching region 130 by the use of specialized line-end structures in the photomask 131. This helps to reduce visible burl defects at the stitching points.

Each of the exposure fields is smaller than the area that the complete pattern is intended to cover (e.g., smaller than the die size, for example). As such, it is desirable to stitch the fields together in the stitching region 130 form the complete pattern. Any desirable size and shape is possible for the first exposure field 134, the second exposure field 136, and the photomask 131, or multiple photomasks in embodiments that use separate masks. However, in various embodiments, the first exposure field 134 and the second exposure field 136 have a similar size and shape, such as when a single photomask is used for both exposures. In some cases, such as when a higher numerical aperture is used during the exposure process, one dimension of the exposure fields may be scaled differently than the other dimension.

In this specific example, the first exposure field 134 has a first longitudinal dimension 135 and the second exposure field 136 has a second longitudinal dimension 137 that together form a total longitudinal dimension 138 of a combined region 141. As illustrated in FIG. 1, the first exposure field 134 and the second exposure field 136 both have a lateral dimension 139 equal to the lateral dimension of the combined region 141. However, stitching may also be applied in the lateral direction. For example, more than two exposure fields may be used to cover the combined region 141 in some embodiments, such as additional exposure fields in the longitudinal direction as well as the lateral direction, if desired. Further configurations will be apparent to those of skill in the art in view of this disclosure.

As discussed in the foregoing, the stitching region 130 may include stitching defects between features of the first exposure field 134 and features of the second exposure field 136. The features formed by exposing the fields have connecting sidewalls that run in the longitudinal direction, a specific example of which is a pattern of lines (illustrated and described using subsequent Figures). It is desirable to reduce stitching defects to improve device performance.

FIG. 2 schematically illustrates an example photolithography system that includes a photomask that is used to form a pattern of lines on a substrate using two separate exposure fields in accordance with embodiments of the invention. The photolithography system of FIG. 2 may be a specific implementation of other photolithography systems described herein such as the photolithography system of FIG. 1, for example. Similarly labeled elements may be as previously described.

Referring to FIG. 2, a photolithography system 200 includes a substrate 210 that has a pattern of lines 220 formed thereon. It should be noted that here and in the following figures a convention has been adopted for brevity and clarity wherein elements adhering to the pattern [x10], where ‘x’ is the Figure number, may be related implementations of a substrate in various embodiments. For example, the substrate 210 may be similar to the substrate 110 except as otherwise stated. An analogous convention has also been adopted for other elements as made clear by the use of similar terms in conjunction with the aforementioned numbering system. For example, the substrate 210 may be a specific example of the substrate 110 where the features are a pattern of lines and a photosensitive layer has been exposed and developed to form the pattern of lines 220.

A first subset of lines 224 has been formed using a first exposure field while a second subset of lines 226 has been formed using a second exposure field. The first and second exposure fields together form a combined region 241. As before, each of the fields (and therefore each of the first subset of lines 224 and the second subset of lines 226) are smaller than the complete pattern. Continuing the example dimensions of FIG. 1, the first subset of lines 224 are formed in an exposure field having a first longitudinal dimension 235 whereas the second subset of lines 226 are formed in an exposure field having a second longitudinal dimension 237 that together form a total longitudinal dimension 238 of the combined region 241. The exposure fields share a lateral dimension 239 equal to the lateral dimension of the combined region 241. It should be noted that there is no requirement that the respective subsets of lines cover an entire exposure region, are all stitched to another line, or that line features are the only type of feature in the exposure region. Variations to the example shown here will be apparent to those of skill in the art relying on the present disclosure.

A photomask 231 may have been used to expose both of the first and second exposure fields of the combined region 241 during separate exposures (e.g., through different reticles or with different alignment). A development process was then used to form the pattern of lines 220. The first subset of lines 224 and the second subset of lines 226 are stitched together in a stitching region 230. Here, the stitching region 230 is depicted as an idealized case where ends of the lines are stitched together precisely with not defects to form continuous lines.

In practice, stitching defects (not shown) will be present in the stitching region 230 due to alignment variability, among other factors. Indeed, although the type and extent of the stitching defects may vary depending on the specific details of a given implementation, the stitching defects may be unavoidable due to the desire to ensure reliable connection between the stitched features. As feature sizes become smaller (e.g., fine pitch line patterns formed using High-NA EUV lithography, for example) stitching defects become both untenable and unavoidable. However, the pattern of lines 220 extends in the longitudinal direction creating longitudinal sidewalls that are stitched together in the stitching region 230. Stitching defects related to the stitching of the longitudinal sidewalls may be reduced by the use of specialized line-end structures, such as described below with respect to FIGS. 3, 4, 5, 6, and 7.

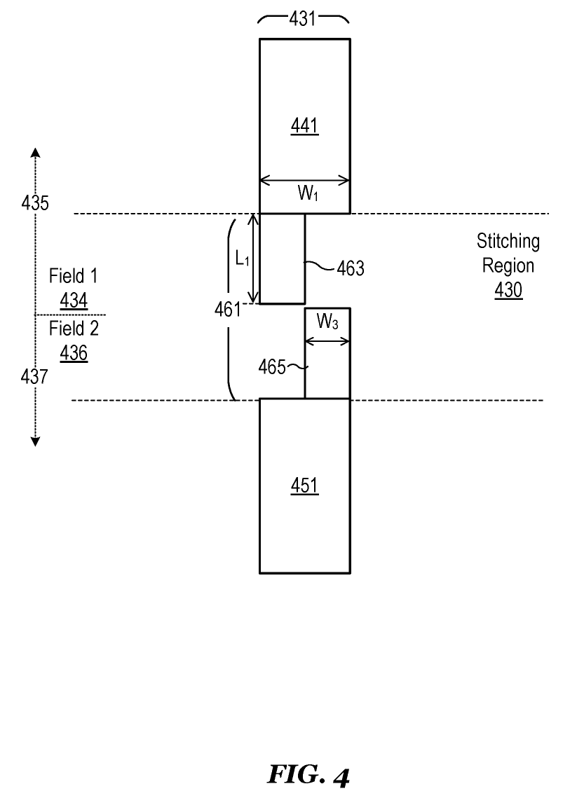

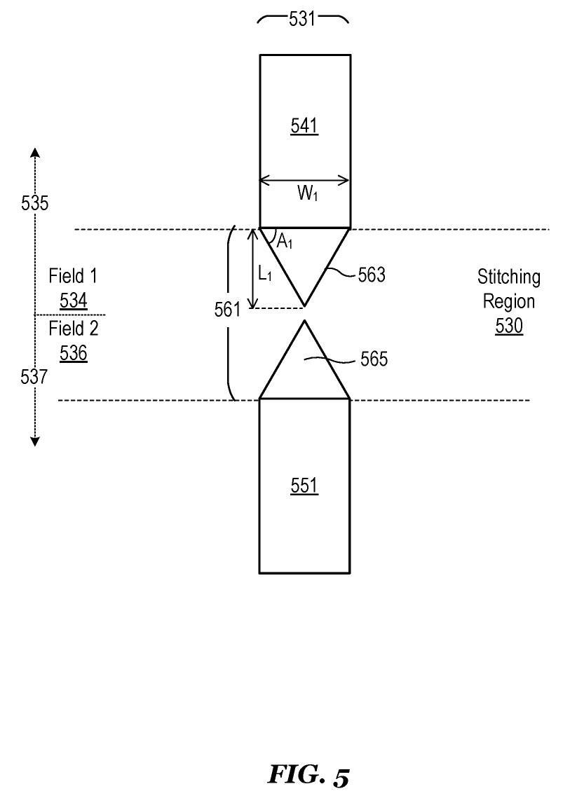

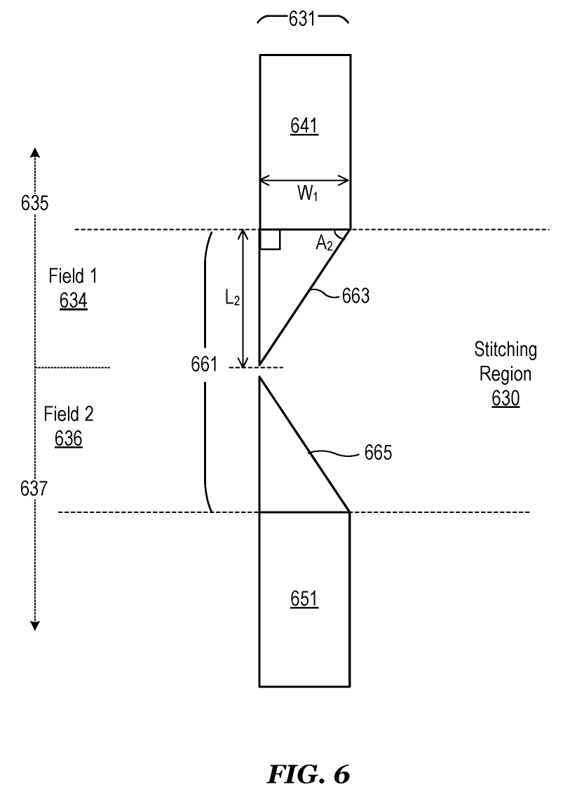

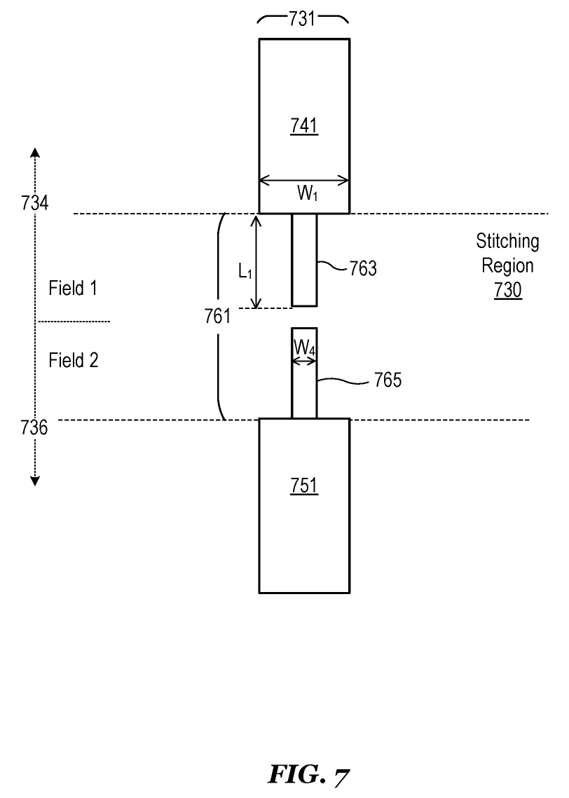

FIGS. 3 through 7 illustrate various line-end designs for photomasks that are utilized to reduce burl size of stitching defects in stitching regions. FIG. 3 illustrates photomask line-ends with a dovetail shape, FIG. 4 illustrates photomask line-ends with a staggered shape, FIG. 5 illustrates photomask line-ends with a tapered shape, FIG. 6 illustrates photomask line-ends with a mitered shape, and FIG. 7 illustrates photomask line-ends with a biased shape.

FIG. 3 illustrates a photomask 331 with a dovetail line-end shape 361, in accordance with some embodiments. The photomask 331 comprises a first transparent area 341 along a first longitudinal dimension 335 and a second transparent area 351 along a second longitudinal dimension 337. Opaque portions of the photomask 331 are not shown in FIG. 3 for simplicity of illustration. The first transparent area 341 is used to expose a top area of a photosensitive layer and thereby form a top portion of a line in a first exposure field 334, and the second transparent area 351 is used to expose a top area of the photosensitive layer and thereby form a bottom portion of a line in a second exposure field 336.

The photomask 331 further comprises a dovetail line-end shape 361 that is also transparent and overlays a stitching region 330. In various embodiments, the dovetail line-end shape 361 includes two top portions 363 extending from the first transparent area 341 in the first exposure field 334 and one bottom portion 365 extending from the second transparent area 351 in the second exposure field 336 aligned between the two top portions 363. In some embodiments, the top portions 363 have a first length L₁ along the first longitudinal dimension 335 that is approximately equal to a first width W₁ of the first transparent area 341 and the second transparent area 351, which corresponds to a width of a subsequently formed line. The bottom portion 365 may also have a same first length L₁ along the second longitudinal dimension 337. In various embodiments, the top portions 363 and the bottom portion 365 have a second width W₂ that is in a range of 25% to 50%, such as about 33%, of the first width W₁.

Although FIG. 3 illustrates the first transparent area 341, the second transparent area 351, and the dovetail line-end shape 361 of the photomask 331 as being simultaneously present over the first exposure field 334 and the second exposure field 336, it should be understood that the exposures may be performed sequentially. For example, in some embodiments, the first transparent area 341 and the two top portions 363 are on a bottom edge of the photomask 331 and the second transparent area 351 and the bottom portion 365 are on a top edge of the photomask 331. The substrate (e.g., a substrate 110 or 210; see above, FIGS. 1 and 2 respectively) is first positioned under the photomask 331 so that the first transparent area 341 and the two top portions 363 are aligned over the first exposure field 334 and the stitching region 330, respectively. Next, after a first exposure (e.g., with structured radiation) is performed, the substrate is moved under the photomask 331 so that the second transparent area 351 and the bottom portion 365 are aligned over the second exposure field 336 and the stitching region 330, respectively. A second exposure (e.g., with structured radiation) is then performed. However, in other embodiments the substrate may be stationary while the photomask 331 is moved.

In still other embodiments, different photomasks may be used for the first and second exposures; in other words, the first transparent area 341 and the two top portions 363 are part of a first photomask while the second transparent area 351 and the bottom portion 365 are part of a second photomask. All such combinations of photomask compositions and positionings are within the scope of the disclosed embodiments.

Although FIG. 3 illustrates a bottom edge of the two top portions 363 being aligned with a top edge of the bottom portion 365, the top and bottom portions of the dovetail line-end shape 361 may be aligned to have the top and bottom edges overlapping in the stitching region 330 by some overlap distance or to have top and bottom edges separated by some distance, which may be referred to as a negative overlap distance. Different offset distances may be selected to modulate the intensity of the radiation dose provided to the stitching region 330 through the dovetail line-end shape 361 and thereby control the shape of the burl at stitching points along lines. For example, rather than a larger, oval-shaped burl on lines at the stitching points, smaller, diamond-shaped burls may be achieved by the use of a specialized line-end shape (e.g., the dovetail line-end shape 361) and a selected offset distance. In some embodiments, the overlap distance between the top and bottom portions of the dovetail line-end shape 361 is in a range of about one half of the first length L₁ to about the first length L₁plus 10 nm[.

FIG. 4 illustrates a photomask 431 with a staggered line-end shape 461, in accordance with some embodiments. The photomask 431 comprises a first transparent area 441 along a first longitudinal dimension 435 and a second transparent area 451 along a second longitudinal dimension 437. Opaque portions of the photomask 431 are not shown in FIG. 4 for simplicity of illustration. The first transparent area 441 is used to expose a top area of a photosensitive layer and thereby form a top portion of a line in a first exposure field 434, and the second transparent area 451 is used to expose a top area of the photosensitive layer and thereby form a bottom portion of a line in a second exposure field 436.

The photomask 431 further comprises a staggered line-end shape 461 that is also transparent and overlays a stitching region 430. In various embodiments, the staggered line-end shape 461 includes a top portion 463 extending from the first transparent area 441 in the first exposure field 434 and a bottom portion 465 extending from the second transparent area 451 in the second exposure field 336. In some embodiments, the top portion 463 has a first length L₁ along the first longitudinal dimension 435 that is approximately equal to a first width W₁ of the first transparent area 341 and the second transparent area 351, which corresponds to a width of a subsequently formed line. The bottom portion 465 may also have a same first length L₁ along the second longitudinal dimension 437. In various embodiments, the top portion 463 and the bottom portion 465 have a third width W₃that is in a range of 33% to 66%, such as about 50%, of the first width W₁. As described above with respect to FIG. 3, all combinations of photomask compositions and positionings for exposures using the staggered line-end shape 461 are within the scope of the disclosed embodiments. The top portion 463 and the bottom portion 465 may be aligned with a positive or negative overlap distance as described above with respect to FIG. 3.

FIG. 5 illustrates a photomask 531 with a tapered line-end shape 561, in accordance with some embodiments. The photomask 531 comprises a first transparent area 541 along a first longitudinal dimension 535 and a second transparent area 551 along a second longitudinal dimension 537. Opaque portions of the photomask 531 are not shown in FIG. 5 for simplicity of illustration. The first transparent area 541 is used to expose a top area of a photosensitive layer and thereby form a top portion of a line in a first exposure field 534, and the second transparent area 551 is used to expose a top area of the photosensitive layer and thereby form a bottom portion of a line in a second exposure field 536.

The photomask 531 further comprises a tapered line-end shape 561 that is also transparent and overlays a stitching region 530. In various embodiments, the tapered line-end shape 561 includes a top portion 563 extending from the first transparent area 541 in the first exposure field 534 and a bottom portion 565 extending from the second transparent area 551 in the second exposure field 536. The top portion 563 and the bottom portion 565 may have isosceles triangular shapes in a top view. In some embodiments, the top portion 563 has a first length L₁along the first longitudinal dimension 535 that is approximately equal to a first width W₁of the first transparent area 541 and the second transparent area 551, which corresponds to a width of a subsequently formed line. The bottom portion 565 may also have a same first length L₁ along the second longitudinal dimension 537. In various embodiments, the top portion 563 and the bottom portion 565 have first angles A₁ between a side extending into the stitching region 530 and the respective boundaries with the first transparent area 541 and the second transparent area 551 that are in a range of 30º to 60º, such as 45º. As described above with respect to FIG. 3, all combinations of photomask compositions and positionings for exposures using the tapered line-end shape 561 are within the scope of the disclosed embodiments. The top portion 563 and the bottom portion 565 may be aligned with a positive or negative overlap distance as described above with respect to FIG. 3.

FIG. 6 illustrates a photomask 631 with a mitered line-end shape 661, in accordance with some embodiments. The photomask 631 comprises a first transparent area 641 along a first longitudinal dimension 635 and a second transparent area 651 along a second longitudinal dimension 637. Opaque portions of the photomask 631 are not shown in FIG. 6 for simplicity of illustration. The first transparent area 641 is used to expose a top area of a photosensitive layer and thereby form a top portion of a line in a first exposure field 634, and the second transparent area 651 is used to expose a top area of the photosensitive layer and thereby form a bottom portion of a line in a second exposure field 636.

The photomask 631 further comprises a mitered line-end shape 661 that is also transparent and overlays a stitching region 630. In various embodiments, the mitered line-end shape 661 includes a top portion 663 extending from the first transparent area 641 in the first exposure field 634 and a bottom portion 665 extending from the second transparent area 651 in the second exposure field 636. The top portion 663 and the bottom portion 665 may have right triangular shapes in a top view. In some embodiments, the top portion 663 has a first length L₁ along the first longitudinal dimension 635 that is approximately equal to a first width W₁ of the first transparent area 641 and the second transparent area 651, which corresponds to a width of a subsequently formed line. The bottom portion 665 may also have a same first length L₁ along the second longitudinal dimension 637. In various embodiments, the top portion 663 and the bottom portion 665 have right angles between a first side extending into the stitching region 530 and the respective boundaries with the first transparent area 541 and the second transparent area 551, and the top portion 663 and the bottom portion 665 have second angles A₂ between a second side extending into the stitching region 530 and the respective boundaries with the first transparent area 541 and the second transparent area 551 that are in a range of 25º to 75º, such as 60º. As described above with respect to FIG. 3, all combinations of photomask compositions and positionings for exposures using the mitered line-end shape 661 are within the scope of the disclosed embodiments. The top portion 663 and the bottom portion 665 may be aligned with a positive or negative overlap distance as described above with respect to FIG. 3.

FIG. 7 illustrates a photomask 731 with a biased line-end shape 761, in accordance with some embodiments. The photomask 731 comprises a first transparent area 741 along a first longitudinal dimension 435 and a second transparent area 751 along a second longitudinal dimension 737. Opaque portions of the photomask 731 are not shown in FIG. 7 for simplicity of illustration. The first transparent area 741 is used to expose a top area of a photosensitive layer and thereby form a top portion of a line in a first exposure field 734, and the second transparent area 751 is used to expose a top area of the photosensitive layer and thereby form a bottom portion of a line in a second exposure field 736.

The photomask 731 further comprises a biased line-end shape 761 that is also transparent and overlays a stitching region 730. In various embodiments, the biased line-end shape 761 includes a top portion 763 extending from the first transparent area 741 in the first exposure field 734 and a bottom portion 765 extending from the second transparent area 751 in the second exposure field 736. The top portion 763 and the bottom portion 765 may be aligned with sidewalls along a same longitudinal direction. In some embodiments, the top portion 763 has a first length L₁ along the first longitudinal dimension 735 that is approximately equal to a first width W₁ of the first transparent area 741 and the second transparent area 751, which corresponds to a width of a subsequently formed line. The bottom portion 765 may also have a same first length L₁ along the second longitudinal dimension 737. In various embodiments, the top portion 763 and the bottom portion 765 have a fourth width W₄ that is in a range of 25% to 50%, such as about 33%, of the first width W₁. As described above with respect to FIG. 3, all combinations of photomask compositions and positionings for exposures using the biased line-end shape 761 are within the scope of the disclosed embodiments. The top portion 763 and the bottom portion 765 may be aligned with a positive or negative overlap distance as described above with respect to FIG. 3.

In various embodiments, a method for calibrating a stitching overlap includes creating an overlay stitching calibration curve using preprogrammed offsets of stitching targets. A critical dimension scanning electron microscope (CD-SEM) is used to measure critical dimensions (CDs) of lines in a pattern of lines formed on a substrate, such as described above with respect to FIG. 2. The CD-SEM may be used to measure overlays (also referred to as overlay figures) between stitched fields using stitching targets (e.g., particular patterns of lines). An X overlay is the difference in position between a top center point at the top of a line and a bottom center point at the bottom of a line. A Y overlay is a function of a size of a burl present at a stitching point. For example, the Y overlay may be computed by converting the burl size to an overlay number which may be done by creating a calibration curve from measurements of burl size resulting at different predefined overlay offsets taken from the reticle design. A function (e.g., a linear function or curve) is then fit to the calibration curve to find the Y overlay. A zero (“0”) overlap may equal the target size of the critical dimension of the line (in other words, the line width).

A stitching overlap calibration curve is generated by performing stitching using a range of overlap distances, for example overlap distances between top and bottom portions of a dovetail line-end shape 361 (see above, FIG. 3). As an example, patterns of lines may be generated using overlap distances in a range of -10 nm to 25, such as -10 nm, 0 nm, +10 nm, +20 nm, and +25 nm. However, any suitable ranges and data points may be used. The X overlay and the Y overlay are measured with a CD-SEM at each overlap distance data point, and between the X overlay or the Y overlay may be plotted against the overlap distances. As such, a preferable overlap distance for achieving a desired X overlay and Y overlay may be determined.

FIG. 8 illustrates a process flow chart diagram for a method 1000 of processing a substrate, in accordance with some embodiments. In step 1010, a first region of a photosensitive layer of the substrate is exposed to structured radiation through a first photomask, as described above with respect to FIG. 3. The first photomask includes a first transparent area and a first transparent line-end extending from the first transparent area. The first transparent line-end is positioned over a stitching region adjacent the first region. The first transparent area has a first width and the first transparent line-end has a second width smaller than the first width.

In step 1020, after exposing the first region, a second region of the photosensitive layer is exposed to structured radiation through a second photomask, as described above with respect to FIG. 3. The second region is adjacent the stitching region opposite the first region. The second photomask includes a second transparent area and a second transparent line-end extending from the second transparent area. The second transparent line-end is positioned over the stitching region.

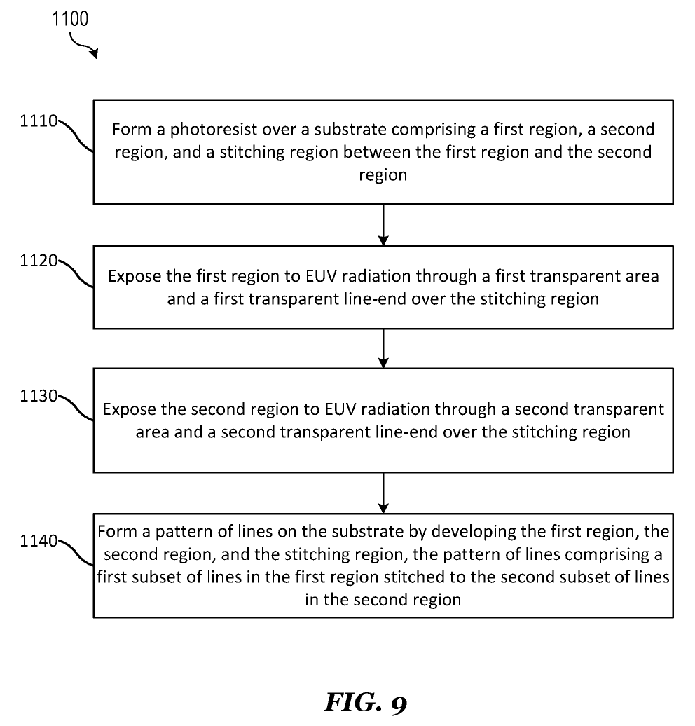

FIG. 9 illustrates a process flow chart diagram for a method 1100 of processing a substrate, in accordance with some embodiments. In step 1110, a photoresist is formed over the substrate including a first region, a second region, and a stitching region between the first region and the second region, as described above with respect to FIG. 3.

In step 1120, the first region is exposed to extreme ultraviolet (EUV) radiation through a first transparent area and a first transparent line-end extending from the first transparent area over the stitching region, as described above with respect to FIG. 3. The first transparent line-end is narrower than the first transparent area.

In step 1130, the second region is exposed to EUV radiation through a second transparent area and a second transparent line-end extending from the second transparent area over the stitching region, as described above with respect to FIG. 3. The second transparent line-end is narrower than the second transparent area as described above with respect to FIG. 3.

In step 1140, a pattern of lines is formed on the substrate by developing the first region, the second region, and the stitching region, as described above with respect to FIG. 2. The pattern of lines includes a first subset of lines in the first region and a second subset of lines in the second region. The first subset of lines is stitched to the second subset of lines in the stitching region, as described above with respect to FIGS. 2 and 3.

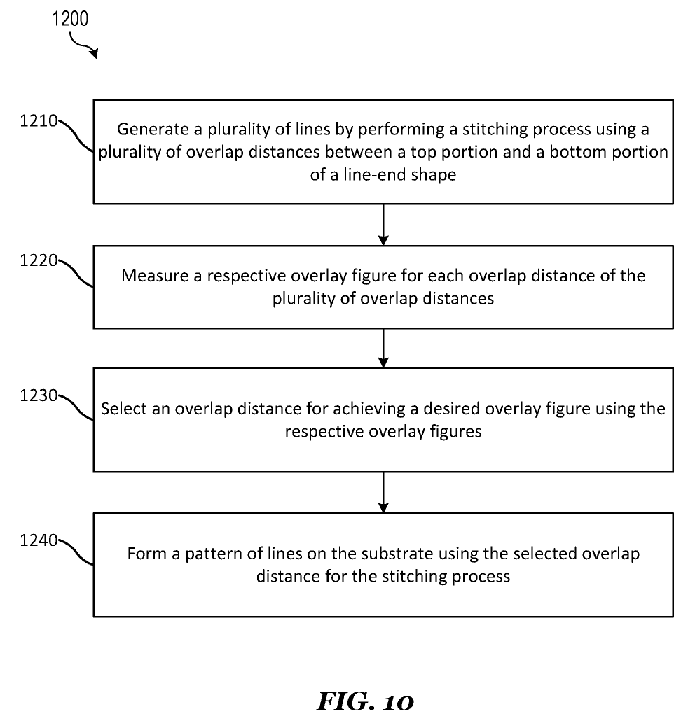

FIG. 10 illustrates a process flow chart diagram for a method 1200 of processing a substrate, in accordance with some embodiments. In step 1210, a plurality of line patterns is generated by performing a stitching process using a plurality of overlap distances between a top portion and a bottom portion of a line-end shape, as described above with respect to FIG. 3.

In step 1220, a respective overlay figure is measured for each overlap distance of the plurality of overlap distances. In step 1230, an overlap distance is selected for achieving a desired overlay figure using the respective overlay figures. In step 1240, a pattern of lines is formed on the substrate using the selected overlap distance for the stitching process, as described above with respect to FIGS. 2 and 3.

Example embodiments of the disclosure are summarized here. Other embodiments can also be understood from the entirety of the specification as well as the claims filed herein.

Example 1. A method of processing a substrate, the method including: exposing a first region of a photosensitive layer of the substrate to structured radiation through a first photomask, the first photomask including a first transparent area and a first transparent line-end extending from the first transparent area, the first transparent line-end being positioned over a stitching region adjacent the first region, the first transparent area having a first width, the first transparent line-end having a second width smaller than the first width; and after exposing the first region, exposing a second region of the photosensitive layer to structured radiation through a second photomask, the second region being adjacent the stitching region opposite the first region, the second photomask including a second transparent area and a second transparent line-end extending from the second transparent area, the second transparent line-end being positioned over the stitching region.

Example 2. The method of example 1, where the first photomask and the second photomask are a same photomask.

Example 3. The method of example 2, where the photosensitive layer is moved relative to the same photomask between exposing the first region and exposing the second region.

Example 4. The method of one of examples 2 or 3, where the first transparent line-end is on a bottom edge of the same photomask and the second transparent line-end is on a top edge of the same photomask.

Example 5. The method of one of examples 1 to 4, where the first transparent line-end and the second transparent line-end have a dovetail shape.

Example 6. The method of one of examples 1 to 4, where the first transparent line-end and the second transparent line-end have respective tapered shapes.

Example 7. The method of one of examples 1 to 4, where the first transparent line-end and the second transparent line-end have staggered positions.

Example 8. The method of one of examples 1 to 4, where the first transparent line-end and the second transparent line-end have respective mitered shapes.

Example 9. The method of one of examples 1 to 8, where the structured radiation is extreme ultraviolet (EUV) radiation.

Example 10. A method of processing a substrate, the method including: forming a photoresist over the substrate, the photoresist including a first region, a second region, and a stitching region between the first region and the second region; exposing the first region to extreme ultraviolet (EUV) radiation through a first transparent area and a first transparent line-end extending from the first transparent area over the stitching region, the first transparent line-end being narrower than the first transparent area; exposing the second region to EUV radiation through a second transparent area and a second transparent line-end extending from the second transparent area over the stitching region, the second transparent line-end being narrower than the second transparent area; and forming a pattern of lines on the substrate by developing the first region, the second region, and the stitching region, the pattern of lines including a first subset of lines in the first region and a second subset of lines in the second region, the first subset of lines being stitched to the second subset of lines in the stitching region.

Example 11. The method of example 10, where the first transparent line-end has a width in a range of 25% to 50% of a width of the first transparent area.

Example 12. The method of one of examples 10 or 11, where the first transparent line-end has a length approximately equal to a width of the first transparent area.

Example 13. The method of example 10, where the second transparent line-end has a width in a range of 33% to 66% of a width of the first transparent area.

Example 14. The method of example 10, where the first transparent line-end has an angle between a side of the first transparent line-end extending into the stitching region and a boundary between the first transparent line-end and the first transparent area, the angle being in a range of 30º to 60º.

Example 15. The method of example 10, where the first transparent line-end has a first angle between a first side of the first transparent line-end extending into the stitching region and a boundary between the first transparent line-end and the first transparent area, the first angle being a right angle.

Example 16. The method of example 15, where the first transparent line-end has a second angle between a second side of the first transparent line-end extending into the stitching region and the boundary between the first transparent line-end and the first transparent area, the second angle being in a range of 25º to 75º.

Example 17. The method of one of examples 10 to 12, where the first transparent line-end and the second transparent line-end form a dovetail shape.

Example 18. A method of processing a substrate, the method including: generating a plurality of line patterns by performing a stitching process, the stitching process using a plurality of overlap distances between a top portion and a bottom portion of a line-end shape; measuring a respective overlay figure for each overlap distance of the plurality of overlap distances; selecting an overlap distance for achieving a desired overlay figure using the respective overlay figures; and forming a pattern of lines on the substrate using the selected overlap distance for the stitching process.

Example 19. The method of example 18, where the overlay figure is a difference in position between a top center point at the top of a line and a bottom center point at the bottom of the line.

Example 20. The method of example 18, where the overlay figure is determined using a burl size at a stitching point.

While this invention has been described with reference to illustrative embodiments, this description is not intended to be construed in a limiting sense. Various modifications and combinations of the illustrative embodiments, as well as other embodiments of the invention, will be apparent to persons skilled in the art upon reference to the description. It is therefore intended that the appended claims encompass any such modifications or embodiments.

What is claimed is:

1. A method of processing a substrate, the method comprising:
exposing a first region of a photosensitive layer of the substrate to structured radiation through a first photomask, the first photomask comprising a first transparent area and a first transparent line-end extending from the first transparent area, the first transparent line-end being positioned over a stitching region adjacent the first region, the first transparent area having a first width, the first transparent line-end having a second width smaller than the first width; and
after exposing the first region, exposing a second region of the photosensitive layer to structured radiation through a second photomask, the second region being adjacent the stitching region opposite the first region, the second photomask comprising a second transparent area and a second transparent line-end extending from the second transparent area, the second transparent line-end being positioned over the stitching region.

2. The method of claim 1, wherein the first photomask and the second photomask are a same photomask.

3. The method of claim 2, wherein the photosensitive layer is moved relative to the same photomask between exposing the first region and exposing the second region.

4. The method of claim 2, wherein the first transparent line-end is on a bottom edge of the same photomask and the second transparent line-end is on a top edge of the same photomask.

5. The method of claim 1, wherein the first transparent line-end and the second transparent line-end have a dovetail shape.

6. The method of claim 1, wherein the first transparent line-end and the second transparent line-end have respective tapered shapes.

7. The method of claim 1, wherein the first transparent line-end and the second transparent line-end have staggered positions.

8. The method of claim 1, wherein the first transparent line-end and the second transparent line-end have respective mitered shapes.

9. The method of claim 1, wherein the structured radiation is extreme ultraviolet (EUV) radiation.

10. A method of processing a substrate, the method comprising:
forming a photoresist over the substrate, the photoresist comprising a first region, a second region, and a stitching region between the first region and the second region;
exposing the first region to extreme ultraviolet (EUV) radiation through a first transparent area and a first transparent line-end extending from the first transparent area over the stitching region, the first transparent line-end being narrower than the first transparent area;
exposing the second region to EUV radiation through a second transparent area and a second transparent line-end extending from the second transparent area over the stitching region, the second transparent line-end being narrower than the second transparent area; and
forming a pattern of lines on the substrate by developing the first region, the second region, and the stitching region, the pattern of lines comprising a first subset of lines in the first region and a second subset of lines in the second region, the first subset of lines being stitched to the second subset of lines in the stitching region.

11. The method of claim 10, wherein the first transparent line-end has a width in a range of 25% to 50% of a width of the first transparent area.

12. The method of claim 10, wherein the first transparent line-end has a length approximately equal to a width of the first transparent area.

13. The method of claim 10, wherein the second transparent line-end has a width in a range of 33% to 66% of a width of the first transparent area.

14. The method of claim 10, wherein the first transparent line-end has an angle between a side of the first transparent line-end extending into the stitching region and a boundary between the first transparent line-end and the first transparent area, the angle being in a range of 30º to 60º.

15. The method of claim 10, wherein the first transparent line-end has a first angle between a first side of the first transparent line-end extending into the stitching region and a boundary between the first transparent line-end and the first transparent area, the first angle being a right angle.

16. The method of claim 15, wherein the first transparent line-end has a second angle between a second side of the first transparent line-end extending into the stitching region and the boundary between the first transparent line-end and the first transparent area, the second angle being in a range of 25º to 75º.

17. The method of claim 10, wherein the first transparent line-end and the second transparent line-end form a dovetail shape.

18. A method of processing a substrate, the method comprising:
generating a plurality of line patterns by performing a stitching process, the stitching process using a plurality of overlap distances between a top portion and a bottom portion of a line-end shape;
measuring a respective overlay figure for each overlap distance of the plurality of overlap distances;
selecting an overlap distance for achieving a desired overlay figure using the respective overlay figures; and
forming a pattern of lines on the substrate using the selected overlap distance for the stitching process.

19. The method of claim 18, wherein the overlay figure is a difference in position between a top center point at the top of a line and a bottom center point at the bottom of the line.

20. The method of claim 18, wherein the overlay figure is determined using a burl size at a stitching point.
